(19) United States
(12) Patent Application Publication
(10) Pub. No.: US 2026/0363069 A1
(43) Pub. Date: Nov. 12, 2026

(54) SEMICONDUCTOR PACKAGE WITH HEAT DISSIPATION STRUCTURE

(71) Applicant: Samsung Electronics Co., Ltd., Suwon-si (KR)

(72) Inventors: Hyeonjeong Hwang, Suwon-si, Gyeonggi-do (KR); Sehoon Jang, Suwon-si (KR)

(21) Appl. No.: 19/427,463

(22) Filed: Dec. 19, 2025

(30) Foreign Application Priority Data
May 12, 2025 (KR) 10-2025-0061262

(51) Int. Cl. H10W 40/20; H10W 74/10

(52) U.S. Cl. CPC H10W 40/242; H10W 40/235; H10W 74/114

(57) ABSTRACT

A semiconductor package includes a lower insulating layer, lower redistribution layers, a semiconductor chip, an encapsulant, an upper insulating layer on the encapsulant, upper redistribution layers, a heat dissipation member, and a heat dissipation structure below the heat dissipation member and including a plurality of heat dissipation layers spaced apart from each other in a vertical direction. The plurality of heat dissipation layers of the heat dissipation structure include a first mesh pattern layer within the upper insulating layer and including a plurality of first through-holes, a second mesh pattern layer at a higher level than the first mesh pattern layer within the upper insulating layer and including a plurality of second through-holes misaligned relative to the plurality of first through-holes along a plane perpendicular to the vertical direction, and a plate layer on the upper insulating layer and contacting the heat dissipation member.

### CROSS-REFERENCE TO RELATED APPLICATIONS

This application claims the benefit under 35 USC 119(a) of Korean Patent Application No. 10-2025-0061262 filed on May 12, 2025 in the Korean Intellectual Property Office, the disclosure of which is incorporated herein by reference in its entirety.

### TECHNICAL FIELD

The present disclosure relates to a semiconductor package and a method of manufacturing the same.

### BACKGROUND

As electronic devices become lighter and more powerful, the development of smaller and high-performance semiconductor chips is required. To improve the reliability of high-performance semiconductor chips, heat dissipation of semiconductor packages becomes more important.

### SUMMARY

Example implementations provide a semiconductor package with improved reliability and a method of manufacturing the same.

According to example implementations, a semiconductor package includes a lower insulating layer; lower redistribution layers within the lower insulating layer; a semiconductor chip disposed on the lower insulating layer and electrically connected to the lower redistribution layers; an encapsulant covering the semiconductor chip, on the lower insulating layer; an upper insulating layer on the encapsulant; upper redistribution layers disposed within the upper insulating layer and electrically connected to the lower redistribution layers; a heat dissipation member on the upper insulating layer; and a heat dissipation structure disposed below the heat dissipation member and including a plurality of heat dissipation layers spaced apart from each other in a vertical direction. The plurality of heat dissipation layers of the heat dissipation structure include a first mesh pattern layer disposed within the upper insulating layer and including a plurality of first through-holes; a second mesh pattern layer disposed at a higher level than the first mesh pattern layer within the upper insulating layer and including a plurality of second through-holes misaligned relative to the plurality of first through-holes along a plane perpendicular to the vertical direction; and a plate layer contacting the heat dissipation member, on the upper insulating layer.

According to example implementations, a semiconductor package includes a lower redistribution structure including a lower insulating layer and lower redistribution layers within the lower insulating layer; a first semiconductor chip disposed on the lower redistribution structure and electrically connected to the lower redistribution layers; an encapsulant disposed on the lower redistribution structure and covering the first semiconductor chip; an upper redistribution structure disposed on the encapsulant and including an upper insulating layer and upper redistribution layers within the upper insulating layer; conductive posts extending in a vertical direction within the encapsulant and electrically connecting the lower redistribution layers and the upper redistribution layers; a heat dissipation member on the upper redistribution structure; second semiconductor chips disposed on at least both sides of the heat dissipation member, on the upper redistribution structure, and electrically connected to the upper redistribution layers; and a heat dissipation structure disposed below the heat dissipation member, and including a plurality of heat dissipation layers spaced apart from each other in a vertical direction and a plurality of heat dissipation vias connecting the plurality of heat dissipation layers. An uppermost heat dissipation layer among the plurality of heat dissipation layers is disposed on the upper insulating layer and in contact with the heat dissipation member, and remaining heat dissipation layers among the plurality of heat dissipation layers are disposed within the upper insulating layer, and each of the remaining heat dissipation layers among the plurality of heat dissipation layers includes a plurality of through-holes.

According to example implementations, a semiconductor package includes a lower redistribution structure including a lower insulating layer and lower redistribution layers within the lower insulating layer; a semiconductor chip disposed on the lower redistribution structure and electrically connected to the lower redistribution layers; an encapsulant covering the semiconductor chip, on the lower redistribution structure; an upper redistribution structure disposed on the encapsulant and including an upper insulating layer and upper redistribution layers within the upper insulating layer; a heat dissipation member disposed on the upper redistribution structure and including a thermal interface material layer and a heat slug on the thermal interface material layer; and a heat dissipation structure disposed below the heat dissipation member and including a plurality of heat dissipation layers spaced apart from each other in a vertical direction. The plurality of heat dissipation layers include internal heat dissipation layers within the upper insulating layer and an upper heat dissipation layer on the upper insulating layer, and a planar area of the upper heat dissipation layer is larger than a planar area of each of the internal heat dissipation layers.

### BRIEF DESCRIPTION OF DRAWINGS

The above and other aspects, features, and advantages of the present disclosure will be more clearly understood from the following detailed description, taken in conjunction with the accompanying drawings.

FIG. 1A is a schematic plan view of a semiconductor package according to example implementations.

FIG. 1B is a schematic cross-sectional view of a semiconductor package according to example implementations.

FIGS. 2A- 2C are schematic plan views of some components of a semiconductor package according to example implementations.

FIG. 3 is a schematic perspective view of some components of a semiconductor package according to example implementations.

FIG. 4 is a schematic cross-sectional view of a semiconductor package according to example implementations.

FIG. 5 is a schematic cross-sectional view of a semiconductor package according to example implementations.

FIGS. 6-15 are schematic cross-sectional views illustrating a process sequence for explaining a method of manufacturing a semiconductor package according to example implementations.

### DETAILED DESCRIPTION

Hereinafter, example implementations will be described with reference to the attached drawings. Hereinafter, terms such as ‘on,’ ‘upper portion,’ ‘upper surface,’ ‘above,’ ‘lower,’ ‘lower portion,’ ‘lower surface,’ ‘below,’ ‘side,’ etc. may be understood to refer to the drawings, except in cases where they are separately referred to by being indicated with drawing symbols. The ‘upper end’ of a certain configuration means a part located at the highest level based on the drawing, and the ‘lower end’ of a certain configuration means a part located at the lowest level based on the drawing. ‘Level’ means a position disposed along the vertical direction (Z-direction) based on the drawing, and may be understood to be located at a higher level the further upward it is located in the vertical direction.

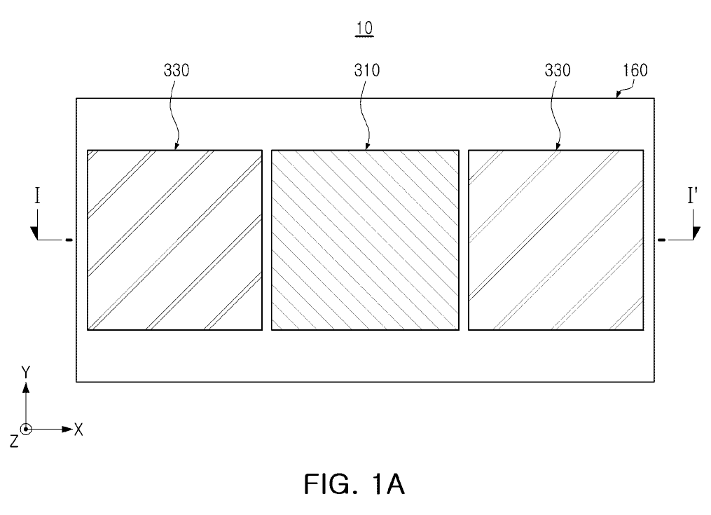

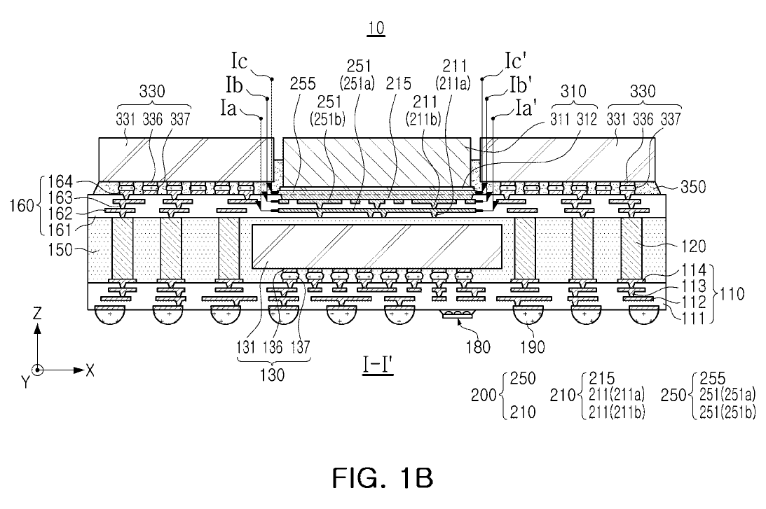

FIG. 1A is a schematic plan view of a semiconductor package according to example implementations. For convenience of explanation, only some components of the semiconductor package are illustrated in FIG. 1A.

FIG. 1B is a schematic cross-sectional view of a semiconductor package according to example implementations. FIG. 1B schematically illustrates a cross-section taken along line Ⅰ-Ⅰ’ of FIG. 1A.

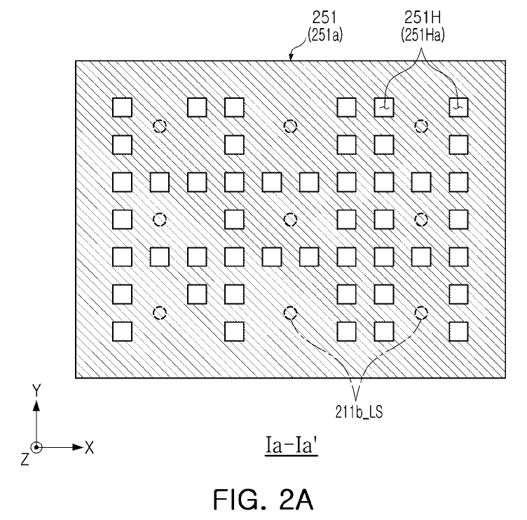

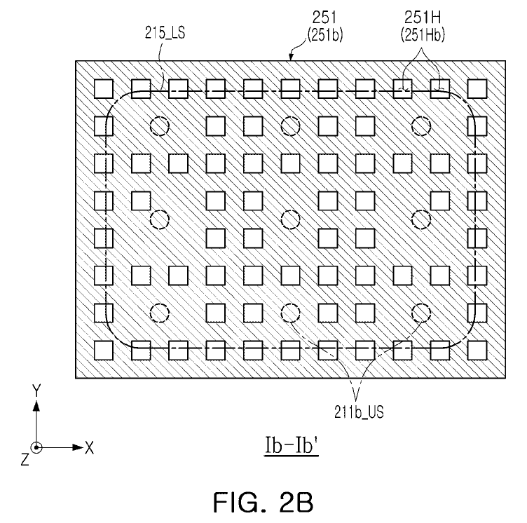

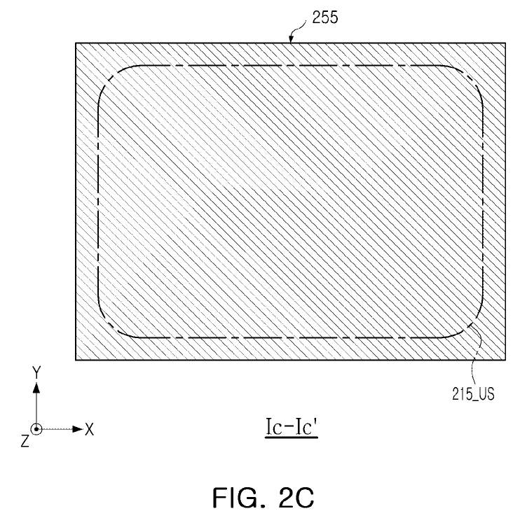

FIGS. 2A-2C are schematic plan views of some components of a semiconductor package according to example implementations. FIGS. 2A-2C schematically illustrate planes taken along lines Ⅰa-Ⅰa,’ Ⅰb-Ⅰb,’ and Ⅰc-Ⅰc’ of FIG. 1B. For convenience of explanation, only some components of the semiconductor package are illustrated in FIGS. 2A-2C. FIG. 2A illustrates a first mesh pattern layer 251a, and schematically illustrates contact areas between the first through-holes 251Ha included in the first mesh pattern layer 251a and the lower surfaces 211b_LS of the intermediate heat dissipation vias 211b. FIG. 2B illustrates a second mesh pattern layer 251b, and schematically illustrates contact areas between the second through-holes 251Hb included in the second mesh pattern layer 251b, the upper surfaces 211b_US of the intermediate heat dissipation vias 211b, and the lower surface 215_LS of the upper heat dissipation via 215. FIG. 2C illustrates a plate layer 255, and schematically illustrates a contact area with the upper surface 215_US of the upper heat dissipation via 215.

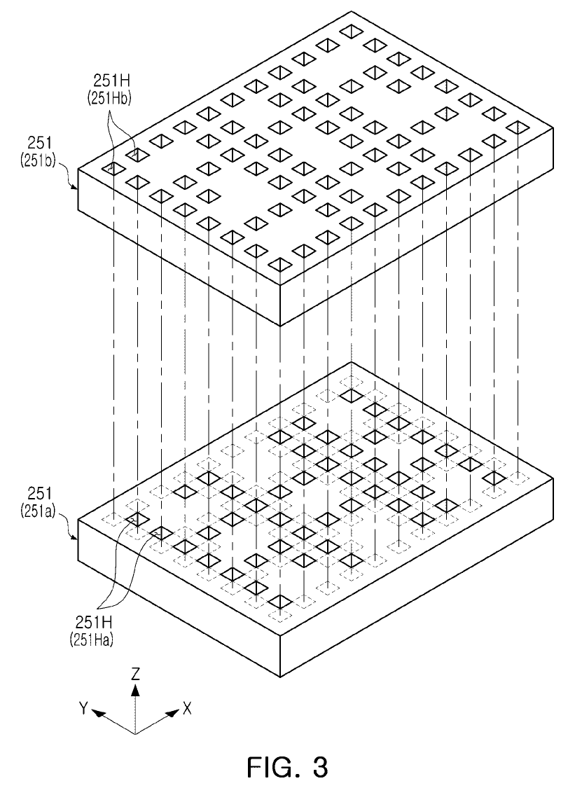

FIG. 3 is a schematic perspective view of a part of a semiconductor package according to example implementations. FIG. 3 schematically illustrates a first mesh pattern layer 251a and a second mesh pattern layer 251b, which may be included in a heat dissipation structure 200 of a semiconductor package 10. FIG. 3 is intended to describe that the first through-holes 251Ha and the second through-holes 251Hb are misaligned relative to each other along a plane perpendicular to the vertical direction (Z-direction), and may not illustrate an example of an actual separation distance between the first mesh pattern layer 251a and the second mesh pattern layer 251b. The number of through-holes 251H, the arrangement pattern of the through-holes 251H, and the like illustrated in FIG. 3 are arbitrarily illustrated for convenience of explanation.

In a Package on Package (PoP) structure including a second semiconductor chip 330 on an upper redistribution structure 160, the semiconductor package may include a heat dissipation member 310 to improve the heat dissipation characteristics of the semiconductor package. In this case, a warpage phenomenon may occur due to differences in weight, size, or the like between the heat dissipation member 310 and the second semiconductor chip 330. In the semiconductor package according to some implementations, the warpage phenomenon of the semiconductor package may be improved by providing a structure in which the second semiconductor chips 330 are symmetrically disposed on both sides of the heat dissipation member 310. In addition, the semiconductor package according to some implementations may include a heat dissipation structure 200 disposed below the heat dissipation member 310. The heat dissipation structure 200 may be formed by the same process as the upper redistribution layers 162 and upper redistribution vias 163 of the upper redistribution structure 160, and may include mesh pattern layers 251 having a plurality of through-holes 251H in the upper insulating layer 161, and a plate layer 255 in contact with the heat dissipation member 310, on the upper insulating layer 161. The semiconductor package according to some implementations includes the heat dissipation structure 200 of the structure as described above, thereby improving the heat dissipation characteristics of the semiconductor package without problems such as an additional process operation or a decrease in process reliability. The detailed configuration and effects of the present disclosure are described above in detail in the description of respective implementations.

Referring to FIGS. 1A, 1B, 2A, 2B, 2C and 3, the semiconductor package 10 may include a lower redistribution structure 110, conductive posts 120, a first semiconductor chip 130, an encapsulant 150, an upper redistribution structure 160, a heat dissipation structure 200, a heat dissipation member 310 and second semiconductor chips 330. The semiconductor package 10 may further include a passive element 180 and external connection conductors 190.

The lower redistribution structure 110 may be a support substrate on which the first semiconductor chip 130 is mounted. The lower redistribution structure 110 may include a lower insulating layer 111, lower redistribution layers 112, lower redistribution vias 113, and lower connection pads 114.

The lower insulating layer 111 may include an insulating resin. The insulating resin may include a thermosetting resin such as an epoxy resin, a thermoplastic resin such as a polyimide, or a resin impregnated with an inorganic filler, for example, a prepreg, Ajinomoto Build-up Film (ABF), FR-4, or Bismaleimide-Triazine (BT). For example, the lower insulating layer 111 may include a photosensitive resin such as Photo-Imageable Dielectric (PID). The lower insulating layer 111 may include a plurality of insulating layers stacked in a vertical direction (Z-axis direction). Depending on the process, the boundary between the plurality of insulating layers may be unclear.

The lower redistribution layers 112 are disposed on or within the lower insulating layer 111 and may redistribute the connection terminals included in the first semiconductor chip 130. According to the description method, the lower redistribution layers 112 may be described as a configuration including lower connection pads 114. The lower redistribution layers 112 may perform various functions depending on the design. For example, the lower redistribution layers 112 may include a ground (GrouND: GND) pattern, a power (PoWeR: PWR) pattern, and a signal (Signal: S) pattern. In this case, the signal (S) pattern may be defined as a transmission path of various signals, such as data signals, excluding ground (GND) patterns, power (PWR) patterns, and the like. The lower redistribution layers 112 may include metals, such as copper (Cu), aluminum (Al), silver (Ag), tin (Sn), gold (Au), nickel (Ni), lead (Pb), titanium (Ti), or alloys thereof. The lower redistribution layers 112 may include more or fewer redistribution layers than those illustrated in the drawing.

The lower redistribution vias 113 may extend vertically within the lower insulating layer 111 and be electrically connected to the lower redistribution layers 112. For example, lower redistribution vias 113 may interconnect lower redistribution layers 112 of different levels, and may interconnect lower connection pads 114 and lower redistribution layers 112. The lower redistribution vias 113 may perform various functions depending on the design. For example, the lower redistribution vias 113 may include ground (GND) vias, power (PoWeR: PWR) vias, and signal (Signal: S) vias. The lower redistribution vias 113 may be filled vias in which a metal material is filled inside a via hole, or conformal vias in which a metal material extends along an inner wall of a via hole. The lower redistribution vias 113 may include a metal material including, for example, copper (Cu), aluminum (Al), silver (Ag), tin (Sn), gold (Au), nickel (Ni), lead (Pb), titanium (Ti), or alloys thereof. The lower redistribution vias 113 may include more or fewer redistribution vias than those illustrated.

The lower connection pads 114 may be disposed on the lower insulating layer 111. According to the description method, the lower connection pads 114 may be described as a configuration included in the lower redistribution layers 112. The lower connection pads 114 may be electrically connected to the conductive posts 120 and the first connection bumps 136 and 137 of the first semiconductor chip 130. The lower connection pads 114 may perform various functions depending on the design. For example, the lower connection pads 114 may include a ground (GND) pad, a power (PoWeR: PWR) pad, and a signal (Signal: S) pad. The lower connection pads 114 may include a metal including, for example, copper (Cu), aluminum (Al), silver (Ag), tin (Sn), gold (Au), nickel (Ni), lead (Pb), titanium (Ti), or alloys thereof. The lower connection pads 114 may include more or fewer redistribution layers than those illustrated in the drawing.

The conductive posts 120 may electrically connect the lower redistribution layers 112 and the upper redistribution layers 162 by penetrating the encapsulant 150. The conductive posts 120 may extend in a vertical direction, for example, in the Z-direction, within the encapsulant 150. An upper surface of the conductive posts 120 is exposed from the encapsulant 150 and may be coplanar with an upper surface of the encapsulant 150. A lower surface of the conductive posts 120 may be in contact with an upper surface of the lower connection pads 114. At least some of the conductive posts 120 may overlap the second semiconductor chips 330 in a vertical direction. The shape of the conductive posts 120 is not limited to a post shape. The conductive posts 120 may include a conductive material, and may include, for example, a metal including copper (Cu), aluminum (Al), silver (Ag), tin (Sn), gold (Au), nickel (Ni), lead (Pb), titanium (Ti), or alloys thereof. In some implementations, a metal seed layer including titanium (Ti), copper (Cu), or the like may be formed on the lower surface of the conductive posts 120.

The first semiconductor chip 130 may be disposed on the lower redistribution structure 110. The first semiconductor chip 130 may be referred to as a semiconductor chip 130 or a lower semiconductor chip 130. The first semiconductor chip 130 may include a first chip body 131 and first connection bumps 136 and 137.

The first chip body 131 may include a semiconductor wafer and a semiconductor wafer integrated circuit (IC) made of a semiconductor element such as silicon, germanium, or a compound semiconductor such as silicon carbide (SiC), gallium arsenide (GaAs), indium arsenide (InAs), and indium phosphide (InP). The first chip body 131 may be a bare semiconductor chip on which no separate bump or interconnection layer is formed, but is not limited thereto, and may also be a packaged type semiconductor chip. The integrated circuit may be a logic circuit (or ‘logic chip’) such as a central processor (CPU), a graphic processor (GPU), a field programmable gate array (FPGA), an application processor (AP), a digital signal processor, an encryption processor, a microprocessor, a microcontroller, an analog-to-digital converter, an application-specific IC (ASIC), but is not limited thereto. In some implementations, the integrated circuit included in the first semiconductor chip 130 may be a memory circuit including volatile memory such as dynamic RAM (DRAM), static RAM (SRAM), and the like, and nonvolatile memory such as phase change RAM (PRAM), magnetic RAM (MRAM), resistive RAM (RRAM), and flash memory. In some implementations, the distance between the upper surface of the first semiconductor chip 130, for example, the upper surface of the first chip body 131, and the lower surface of the upper insulating layer 161 may be 10 μm or less.

The first connection bumps 136 and 137 may be disposed below the first chip body 131. The first connection bumps 136 and 137 may be disposed between the first chip body 131 and the lower connection pads 114 of the lower redistribution structure 110, and the first semiconductor chip 130 may be electrically connected to the lower redistribution layers 112 through the first connection bumps 136 and 137. The first connection bumps 136 and 137 may include more or less than the number illustrated. The first connection bumps 136 and 137 may include first connection pillars 136 and first connection solders 137. The first connection pillars 136 may include a conductive material, and may include, for example, at least one metal material among aluminum (Al), copper (Cu), nickel (Ni), tungsten (W), platinum (Pt), and gold (Au). The first connection solders 137 may include a conductive material, for example, a low melting point metal such as tin (Sn), indium (In), bismuth (Bi), antimony (Sb), copper (Cu), silver (Ag), zinc (Zn), lead (Pb), or alloys (for example, Sn-Ag-Cu) thereof. In some implementations, a lower underfill having a capillary underfill (CUF) structure may be further disposed between the first semiconductor chip 130 and the lower insulating layer 111. In some implementations, the lower underfill may have a molded underfill (MUF) structure that is integrated with the encapsulant 150.

The encapsulant 150 may encapsulate the conductive posts 120 and at least a portion of the first semiconductor chip 130 on the lower redistribution structure 110. The encapsulant 150 may cover at least respective portions of the conductive posts 120 and the first semiconductor chip 130. The encapsulant 150 may include, for example, a thermosetting resin such as an epoxy resin, a thermoplastic resin such as a polyimide, or a prepreg, ABF, FR-4, BT, Epoxy Molding Compound (EMC) in which these resins are impregnated with inorganic fillers.

The passive element 180 may be disposed below the lower surface of the lower redistribution structure 110. In some implementations, the semiconductor package 10 may include at least one passive element 180, and more than the number illustrated may be disposed. The passive element 180 may include, for example, a capacitor, an inductor, beads, and the like. In some implementations, the passive element 180 may be flip-chip bonded to the lower surface of the lower redistribution structure 110. The passive element 180 may be electrically connected to the lower redistribution layers 112 through solder bumps, or the like. An underfill resin may be filled between the passive element 180 and the lower insulating layer 111. The position where the passive element 180 is disposed is not limited to that illustrated, and may be disposed between the first semiconductor chip 130 and the conductive posts 120 on the upper surface of the lower redistribution structure 110.

The external connection conductors 190 may be disposed below the lower surface of the lower redistribution structure 110. The external connection conductors 190 may be electrically connected to the first semiconductor chip 130 and the conductive posts 120 through the lower redistribution layers 112. The semiconductor package 10 may be connected to an external device such as a module substrate or a system board through the external connection conductors 190. In some implementations, the external connection conductors 190 may include a low-melting-point metal, for example, tin (Sn) or an alloy (Sn-Ag-Cu) including tin (Sn). In some implementations, the external connection conductors 190 may have a combined form of a pillar (or underbump metal) and a ball. The pillar may include copper (Cu) or an alloy of copper (Cu), and the ball may include a solder ball.

The upper redistribution structure 160 may be disposed on the encapsulant 150. The upper redistribution structure 160 may be a support substrate to which the heat dissipation member 310 and the second semiconductor chips 330 are bonded. The upper redistribution structure 160 may include an upper insulating layer 161, upper redistribution layers 162, upper redistribution vias 163, and upper connection pads 164.

The upper insulating layer 161 may include an insulating resin. The insulating resin may include a thermosetting resin such as an epoxy resin, a thermoplastic resin such as a polyimide, or a resin impregnated with an inorganic filler, such as prepreg, Ajinomoto Build-up Film (ABF), FR-4, or Bismaleimide-Triazine (BT). For example, the upper insulating layer 161 may include a photosensitive resin such as Photo-Imageable Dielectric (PID). The upper insulating layer 161 may include a plurality of insulating layers stacked in a vertical direction (Z-axis direction). Depending on the process, the boundary between the plurality of insulating layers may be unclear.

The upper redistribution layers 162 are disposed on or within the upper insulating layer 161 and may redistribute the connection terminals included in the second semiconductor chips 330. According to the description method, the upper redistribution layers 162 may be described as a configuration including upper connection pads 164. The upper redistribution layers 162 may include first upper redistribution layers 162 located at the same level as the first mesh pattern layer 251a and second upper redistribution layers 162 located at the same level as the second mesh pattern layer 251b. The upper redistribution layers 162 may perform various functions depending on the design. For example, the upper redistribution layers 162 may include a ground (GND) pattern, a power (PWR) pattern, and a signal (Signal: S) pattern. In this case, the signal (S) pattern may be defined as a transmission path of various signals, such as a data signal, excluding the ground (GND) pattern and the power (PWR) pattern. The upper redistribution layers 162 may include a metal, for example, copper (Cu), aluminum (Al), silver (Ag), tin (Sn), gold (Au), nickel (Ni), lead (Pb), titanium (Ti), or alloys thereof. The upper redistribution layers 162 may include more or fewer redistribution layers than those illustrated in the drawing.

The upper redistribution vias 163 may extend vertically within the upper insulating layer 161 and be electrically connected to the upper redistribution layers 152. For example, the upper redistribution vias 163 may interconnect upper redistribution layers 162 at different levels, and may interconnect upper connection pads 164 and the upper redistribution layers 162. At least some of the upper redistribution vias 163 located at the lowest level among the upper redistribution vias 163 may be in contact with the conductive posts 120. The upper redistribution vias 163 may perform various functions depending on the design. For example, the upper redistribution vias 163 may include a ground (GND) via, a power (PoWeR: PWR) via, and a signal (Signal: S) via. The upper redistribution vias 163 may be filled vias in which a metal material is filled inside the via hole or conformal vias in which a metal material extends along the inner wall of the via hole. The upper redistribution vias 163 may include a metal material including, for example, copper (Cu), aluminum (Al), silver (Ag), tin (Sn), gold (Au), nickel (Ni), lead (Pb), titanium (Ti), or alloys thereof. The upper redistribution vias 163 may include more or fewer redistribution vias than those illustrated.

The upper connection pads 164 may be disposed on the upper insulating layer 161. According to the description method, the upper connection pads 164 may be described as a configuration included in the upper redistribution layers 162. The upper connection pads 164 may be electrically connected to the second connection bumps 336 and 337 of the second semiconductor chip 330. The upper connection pads 164 may perform various functions depending on the design. For example, the upper connection pads 164 may include a ground (GND) pad, a power (PoWeR: PWR) pad, and a signal (Signal: S) pad. The upper connection pads 164 may include a metal including, for example, copper (Cu), aluminum (Al), silver (Ag), tin (Sn), gold (Au), nickel (Ni), lead (Pb), titanium (Ti), or alloys thereof. The upper connection pads 164 may include more or fewer redistribution layers than those illustrated in the drawing.

The heat dissipation structure 200 may be disposed within the upper insulating layer 161. In the vertical direction, the heat dissipation structure 200 may overlap the first semiconductor chip 130 and the heat dissipation member 310. The heat dissipation structure 200 may be spaced apart from the first semiconductor chip 130 and may be in contact with the heat dissipation member 310. The heat dissipation structure 200 may transfer heat generated from the first semiconductor chip 130 to the heat dissipation member 310 to perform a heat dissipation function of the semiconductor package 10. The heat dissipation structure 200 may be electrically isolated from the upper redistribution layers 162. The heat dissipation structure 200 may be electrically isolated from the first semiconductor chip 130 and the second semiconductor chips 330. In some implementations, the heat dissipation structure 200 may include a material such as the upper redistribution layers 162. For example, the heat dissipation structure 200 and the upper redistribution layers 162 may include copper (Cu). In some implementations, the heat dissipation structure 200 may include a metal including copper (Cu), aluminum (Al), silver (Ag), tin (Sn), gold (Au), nickel (Ni), lead (Pb), titanium (Ti), or alloys thereof. The heat dissipation structure 200 may include a plurality of heat dissipation layers 250 and a plurality of heat dissipation vias 210. The plurality of heat dissipation layers 250 may include mesh pattern layers 251 and a plate layer 255.

The mesh pattern layers 251 may be disposed within the upper insulating layer 161 and may be referred to as internal heat dissipation layers 251. The mesh pattern layers 251 may be disposed in multiples, and in FIGS. 1A - 3, the mesh pattern layers 251 are illustrated as an example in which the mesh pattern layers 251 include a first mesh pattern layer 251a and a second mesh pattern layer 251b. The number of mesh pattern layers 251 is not limited thereto, and may be disposed in numbers greater or less than those illustrated. The mesh pattern layers 251 may be disposed at the same level as the upper redistribution layers 162 within the upper insulating layer 161. The first mesh pattern layer 251a and the second mesh pattern layer 251b may be connected to each other through first internal heat dissipation vias 211a disposed therebetween. Each of the mesh pattern layers 251 may include a plurality of through-holes 251H. The plurality of through-holes 251H may be holes that penetrate the mesh pattern layers 251 in a vertical direction (for example, in the Z-direction), and since the mesh pattern layers 251 include a plurality of through-holes 251H, they may have a mesh pattern as illustrated in FIGS. 2A and 2B. The number and arrangement pattern of the through-holes 251H are not limited to those illustrated in FIGS. 2A, 2B, and 3, and may be variously modified. The first mesh pattern layer 251a may include a plurality of first through-holes 251Ha, and the second mesh pattern layer 251b may include a plurality of second through-holes 251Hb.

Referring to FIG. 3, the first through-holes 251Ha of the first mesh pattern layer 251a and the second through-holes 251Hb of the second mesh pattern layer 251b may be misaligned relative to each other along a plane perpendicular to the vertical direction. For example, the first through-holes 251Ha and the second through-holes 251Hb may not overlap each other in the vertical direction, or may only partially overlap each other. At least some of the second through-holes 251Hb may overlap with an area between the first through-holes 251Ha in the vertical direction. Similarly, at least some of the first through-holes 251Ha may overlap with an area between the second through-holes 251Hb in the vertical direction. Since the mesh pattern layers 251 include the through-holes 251H of this structure, the process reliability for forming the internal heat dissipation layers 251 having the mesh pattern within the upper insulating layer 261 may be improved, and the process method may be simplified. In addition, the heat generated from the first semiconductor chip 130 may be transferred to the heat dissipation member 310 through the heat dissipation structure 200, thereby improving the heat dissipation characteristic. In some implementations, the number of the second through-holes 251Hb may be different from the number of the first through-holes 251Ha. For example, the number of the second through-holes 251Hb may be greater than the number of the first through-holes 251Ha. Conversely, the number of the second through-holes 251Hb may be less than the number of the first through-holes 251Ha. In some implementations, the number of the second through-holes 251Hb may be the same as the number of the first through-holes 251Ha. In some implementations, the size of each of the first through-holes 251Ha may be the same as the size of each of the second through-holes 251Hb, but is not limited thereto. For example, the size of each of the first through-holes 251Ha may be larger or smaller than the size of each of the second through-holes 251Hb. In some implementations, the first through-holes 251Ha may be disposed with a uniform size, but may include first through-holes 251Ha of different sizes. In some implementations, the second through-holes 251Hb may be disposed with a uniform size, but may include second through-holes 251Hb of different sizes. The plurality of through-holes 251H may have a polygonal, circular, or oval shape.

The plate layer 255 may be disposed on the upper insulating layer 161 and may be referred to as an upper heat dissipation layer 255. The plate layer 255 may be located at the same level as the upper connection pads 164. Unlike the mesh pattern layers 251, the plate layer 255 may not include through-holes 251H. Since the plate layer 255 does not include a plurality of through-holes 251H, the heat dissipation member 310 may be stably bonded on the heat dissipation structure 200, and the reliability and heat dissipation characteristics of the semiconductor package 10 may be improved. The plate layer 255 may be connected to the second mesh pattern layer 251bthrough the upper heat dissipation via 215. The plate layer 255 may be in contact with the heat dissipation member 310. The plate layer 255 may be in contact with the thermal interface material layer 312 of the heat dissipation member 310. The planar area of the plate layer 255 may be larger than the planar areas of each of the thermal interface material layer 312 and the heat slug 311. The planar area of the plate layer 255 may be larger than the planar area of each of the mesh pattern layers 251. In some implementations, the mesh pattern layers 251 may have a planar area smaller than that of the plate layer 255 because they include through-holes 251H. Since the through-holes 251H are holes that penetrate the mesh pattern layers 251 in a vertical direction, the space occupied by the through-holes 251H may be excluded from the planar area of the mesh pattern layers 251. In some implementations, the mesh pattern layers 251 and the plate layer 255 may have the same total length in the X direction and the Y direction as illustrated in FIGS. 2A-2C, but the mesh pattern layers 251 may have a smaller planar area than the plate layer 255 due to the through-holes 251H.

The plurality of heat dissipation vias 210 may include a plurality of internal heat dissipation vias 211 and an upper heat dissipation via 215. The plurality of heat dissipation vias 210 may be filled vias in which a metal material is filled inside the via hole or conformal vias in which a metal material extends along the inner wall of the via hole. The plurality of internal heat dissipation vias 211 may extend vertically from below the mesh pattern layers 251. The plurality of internal heat dissipation vias 211 may include more or fewer than the number illustrated. The plurality of internal heat dissipation vias 211 may include a first internal heat dissipation via 211a below the first mesh pattern layer 251a and a second internal heat dissipation via 211b below the second mesh pattern layer 251b.

The first internal heat dissipation vias 211a may extend vertically from below the first mesh pattern layer 251a. The description of the first internal heat dissipation vias 211a may be understood as a description of the heat dissipation vias located at the lowest level among the plurality of heat dissipation vias 210. For example, since the semiconductor package 10 of FIG. 1B has a configuration in which the first mesh pattern layer 251a is located at the lowest level among the plurality of heat dissipation layers 250, the first internal heat dissipation vias 211a below the first mesh pattern layer 251a may be heat dissipation vias located at the lowest level among the plurality of heat dissipation vias 210. The first internal heat dissipation vias 211a may be referred to as lower heat dissipation vias 211a. The first internal heat dissipation vias 211a may be located at the same level as the upper redistribution vias 163 located at the lowest level among the redistribution vias 163. The first internal heat dissipation vias 211a may not vertically overlap with the first through-holes 251Ha. The first internal heat dissipation vias 211a may be in contact with the encapsulant 150. A lower surface of the first internal heat dissipation vias 211a may be in contact with an upper surface of the encapsulant 150. The first internal heat dissipation vias 211a may be spaced apart from the first semiconductor chip 130.

The second internal heat dissipation vias 211b extend vertically between the first mesh pattern layer 251a and the second mesh pattern layer 251b and may connect the first mesh pattern layer 251a and the second mesh pattern layer 215b. The description of the second internal heat dissipation vias 211b may be understood as a description of the heat dissipation vias disposed between the mesh pattern layers 251 among the plurality of heat dissipation vias 210. Therefore, when the mesh pattern layers 251 are disposed in three or more, the second internal heat dissipation vias 211b may be disposed at multiple levels.

The second internal heat dissipation vias 211b may be referred to as intermediate heat dissipation vias 211b. The lower surfaces 211b_LS of the second internal heat dissipation vias 211b may be in contact with the upper surface of the first mesh pattern layer 251a, and the upper surfaces 211b_US of the second internal heat dissipation vias 211b may be in contact with the lower surface of the second mesh pattern layer 251b. Referring to FIG. 2A, the lower surfaces 211b_LS of the second internal heat dissipation vias 211b may be located in an area between the first through-holes 251Ha. To secure space for the lower surfaces 211b_LS of the second internal heat dissipation vias 211b, the first through-holes 251Ha of the first mesh pattern layer 251a may be disposed further apart from each other around the lower surfaces 211b_LS of the second internal heat dissipation vias 211b. Referring to FIG. 2B, the upper surfaces 211b_US of the second internal heat dissipation vias 211b may be located in an area between the second through-holes 251Hb. To secure the space of the upper surfaces 211b_US of the second internal heat dissipation vias 211b, the second through-holes 251Hb of the second mesh pattern layer 251b may be disposed further apart from each other around the upper surfaces 211b_US of the second internal heat dissipation vias 211b. The second internal heat dissipation vias 211b may not overlap with the first through-holes 251Ha and the second through-holes 251Hb in the vertical direction.

The upper heat dissipation via 215 may be disposed below the plate layer 255. The upper heat dissipation via 215 may be referred to as a plate heat dissipation via 215. The upper heat dissipation via 215 connected to the plate layer 255 may be disposed as a single unit, unlike the multiple internal heat dissipation vias 211. The upper heat dissipation via 215 may be in contact with the upper surface of the second mesh pattern layer 251b. Referring to FIG. 2B, the lower surface 215_LS of the upper heat dissipation via 215 may overlap at least some of the second through-holes 251Hb. At least some of the second through-holes 251Hb may completely overlap with the upper heat dissipation via 215. An area of the upper surface of the second mesh pattern layer 251b covered by the lower surface 215_LS of the upper heat dissipation via 215 may be wider than an area that is not covered. The internal heat dissipation vias 211 may overlap vertically with the upper heat dissipation via 215. In some implementations, all of the internal heat dissipation vias 211 may overlap vertically with the upper heat dissipation via 215. Like other heat dissipation vias, the cross-sectional area of the upper surface 215_US of the upper heat dissipation via 215 may be larger than the cross-sectional area of the lower surface 215_LS.

A heat dissipation member 310 may be disposed on a heat dissipation structure 200. In some implementations, the heat dissipation member 310 may be disposed between second semiconductor chips 330. The heat dissipation member 310 may overlap the first semiconductor chip 130 in a vertical direction. As the heat dissipation member 310 is disposed between the second semiconductor chips 330, warpage of the semiconductor package may be improved. The heat dissipation member 310 may dissipate heat generated from the first semiconductor chip 130 to the outside. The heat dissipation member 310 may include a heat slug 311 and a thermal interface material layer (TIM) 312.

The thermal interface material layer 312 may be in contact with the upper surface of the plate layer 255 of the heat dissipation structure 200. The thermal interface material layer 312 may fix the heat slug 311 on the heat dissipation structure 200, and the heat generated from the first semiconductor chip 130 may be transferred to the heat slug 311 through the thermal interface material layer 312 via the heat dissipation structure 200. In some implementations, the cross-sectional area of the thermal interface material layer 312 may be larger than the cross-sectional area of the heat slug 311 and smaller than the cross-sectional area of the plate layer 255. The thermal interface material layer 312 may include, for example, a thermally conductive adhesive tape, a thermally conductive grease, a thermally conductive adhesive, and the like.

The heat slug 311 may be disposed on the thermal interface material layer 312. In some implementations, the upper surface of the heat slug 311 may be located at the same level as the upper surfaces of the second semiconductor chips 330. In some implementations, the cross-sectional area of the heat slug 311 may be smaller than the cross-sectional area of the plate layer 255. The heat slug 311 may include a material having excellent thermal conductivity, such as aluminum (Al), gold (Au), silver (Ag), copper (Cu), iron (Fe), graphite, graphene, or the like.

The second semiconductor chips 330 may be disposed spaced apart from the heat dissipation member 310 on the upper redistribution structure 160. The second semiconductor chips 330 may be referred to as upper semiconductor chips 330. In some implementations, the second semiconductor chips 330 may include a different type of semiconductor chip from the first semiconductor chip 130. For example, the first semiconductor chip 130 may include a logic chip, and the second semiconductor chips 330 may include a memory chip. The second semiconductor chip 330 may include a second chip body 331 and second connection bumps 336 and 337.

The second chip body 331 may include a semiconductor wafer and a semiconductor wafer integrated circuit (IC) made of a semiconductor element such as silicon, germanium, or a compound semiconductor such as silicon carbide (SiC), gallium arsenide (GaAs), indium arsenide (InAs), and indium phosphide (InP). The second chip body 331 may be a bare semiconductor chip without a separate bump or interconnection layer formed thereon, but is not limited thereto, and may also be a packaged type semiconductor chip. The integrated circuit may be a memory circuit (or ‘memory chip’) including volatile memory such as dynamic RAM (DRAM), static RAM (SRAM), and the like, and nonvolatile memory such as phase change RAM (PRAM), magnetic RAM (MRAM), resistive RAM (RRAM), and flash memory. In some implementations, the integrated circuit included in the second semiconductor chip 330 may be a logic circuit (or ‘logic chip’) such as a central processor (CPU), a graphics processor (GPU), a field programmable gate array (FPGA), an application processor (AP), a digital signal processor, an encryption processor, a microprocessor, a microcontroller, an analog-to- digital converter, an application-specific IC (ASIC).

The second connection bumps 336 and 337 may be disposed below the second chip body 331. The second connection bumps 336 and 337 may be disposed between the second chip body 331 and the upper connection pads 164 of the upper redistribution structure 160, and the second semiconductor chips 330 may be electrically connected to the upper redistribution layers 162 through the second connection bumps 336 and 337. The second connection bumps 336 and 337 may include more or less than the number illustrated. The second connection bumps 336 and 337 may include second connection pillars 336 and second connection solders 337. The second connection pillars 336 may include a conductive material, and may include, for example, a metal material of at least one of aluminum (Al), copper (Cu), nickel (Ni), tungsten (W), platinum (Pt), and gold (Au). The second connection solders 337 may include a conductive material, for example, a low melting point metal such as tin (Sn), indium (In), bismuth (Bi), antimony (Sb), copper (Cu), silver (Ag), zinc (Zn), lead (Pb), or alloys (e.g., Sn-Ag-Cu) thereof.

The upper underfill 350 may fill at least a portion of a space between the second semiconductor chips 330 and the heat dissipation member 310 on the upper redistribution structure 160. The upper underfill 350 may fill a space between the second connection bumps 336 and 337. The upper underfill 350 may surround at least a portion of the heat dissipation member 310. The upper underfill 350 may physically and electrically protect the heat dissipation member 310 and the second semiconductor chips 330. The upper underfill 350 may include an insulating resin, such as an epoxy resin. The upper underfill 350 may have a capillary underfill (CUF) structure, but is not limited thereto. In some implementations, the upper underfill 350 may not be disposed.

In the following description, descriptions that overlap with those described with reference to FIGS. 1A-3 are omitted.

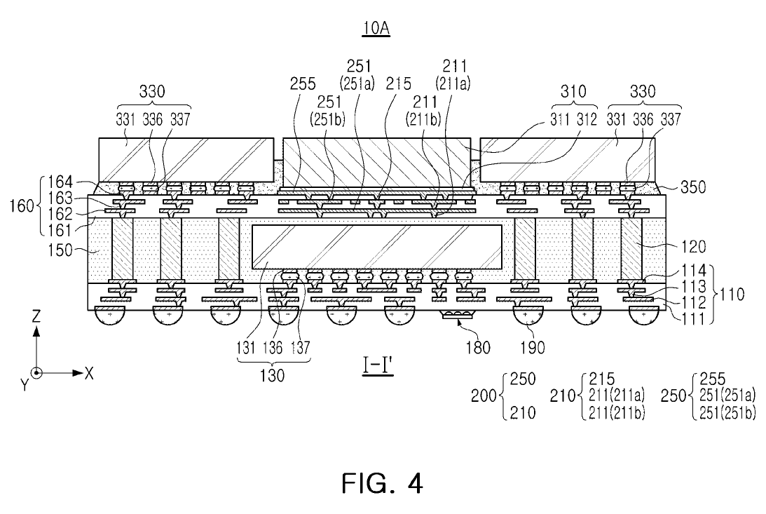

FIG. 4 is a schematic cross-sectional view of a semiconductor package according to example implementations. FIG. 4 illustrates an area corresponding to FIG. 1B.

Referring to FIG. 4, unlike the semiconductor package 10 of FIG. 1B, the semiconductor package 10A may have a plurality of upper heat dissipation vias 215 disposed. Referring also to FIG. 2B, the upper heat dissipation vias 215 of the semiconductor package 10 may be disposed so as not to overlap with the second through-holes 251Hb in the vertical direction, like the second heat dissipation vias 211b. The upper heat dissipation vias 215 may be misaligned relative to the second through-holes 251Hb along a plane perpendicular to the vertical direction. Unlike the intermediate heat dissipation vias 211b disposed between the mesh pattern layers 251, the upper heat dissipation vias 215 connected to the plate layer 255 and the lower heat dissipation vias 211a in contact with the encapsulant 150 may be deformed into various shapes. For example, like the upper heat dissipation via 215 of the semiconductor package 10 of FIG. 1B, the lower heat dissipation via 211a may be disposed singly or may be vertically overlapped with the first through-holes 251Ha. Unlike the upper redistribution vias 163 that electrically connect the upper redistribution layers 162, the plurality of heat dissipation vias 210 only perform a heat dissipation function and not a redistribution function, and therefore may be deformed into various shapes.

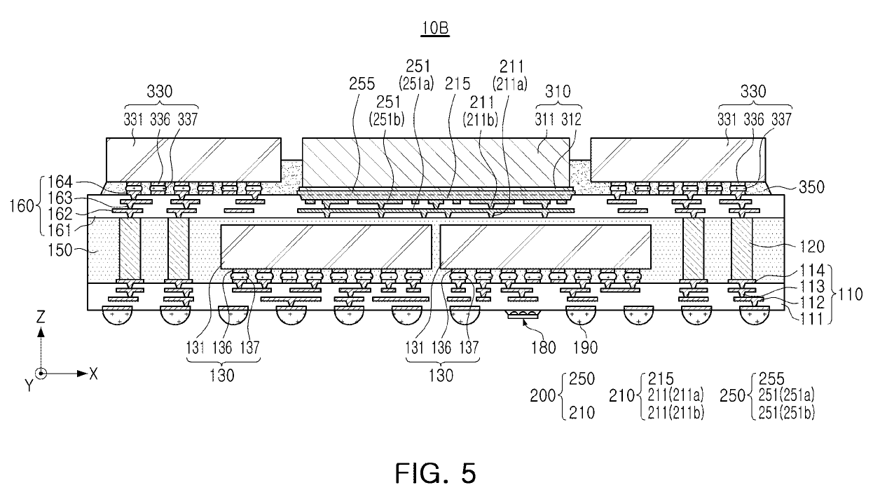

FIG. 5 is a schematic cross-sectional view of a semiconductor package according to example implementations. FIG. 5 illustrates an area corresponding to FIG. 1B.

Referring to FIG. 5, the semiconductor package 10B may include a plurality of first semiconductor chips 130, unlike the semiconductor package 10 of FIG. 1B. For example, the semiconductor package 10B may include two first semiconductor chips 130 and two second semiconductor chips 330. The first semiconductor chips 130 may be disposed to overlap with the heat dissipation member 310 in a vertical direction. In some implementations, the area where the first semiconductor chips 130 overlap with the heat dissipation member 310 in a vertical direction may be larger than the area where the first semiconductor chips 130 overlap with the heat dissipation member 310 in a vertical direction.

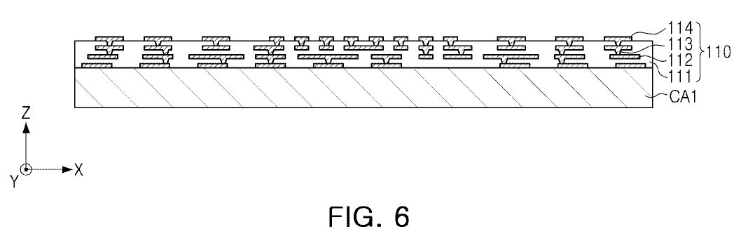

FIGS. 6-15 are schematic cross-sectional views illustrating a method of manufacturing a semiconductor package according to example implementations according to a process sequence. FIGS. 6-15 illustrate an area corresponding to FIG. 1B, and illustrate some implementations of a method of manufacturing a semiconductor package 10 of FIG. 1B.

Referring to FIG. 6, a lower redistribution structure 110 may be formed on a first carrier CA1.

For example, in the case of the first carrier CA1, a polymer layer including a curable resin and a metal layer including nickel (Ni), titanium (Ti), or the like may be sequentially coated on a copper clad laminate (CCL). The lower redistribution structure 110 may include a lower insulating layer 111, lower redistribution layers 112, lower redistribution vias 113, and lower connection pads 114. The lower insulating layer 111 may be formed by sequentially applying and curing a photosensitive material, for example, photoimageable dielectric (PID). The lower redistribution layers 112 and the lower redistribution vias 113 may be formed by performing an exposure process and a development process to form a via hole penetrating the lower insulating layer 111, and patterning a metal material on the lower insulating layer 111 using a plating process. The lower connection pads 114 may be formed on the upper surface of the lower redistribution structure 110, and a barrier layer including nickel (Ni), gold (Au), or the like may be formed.

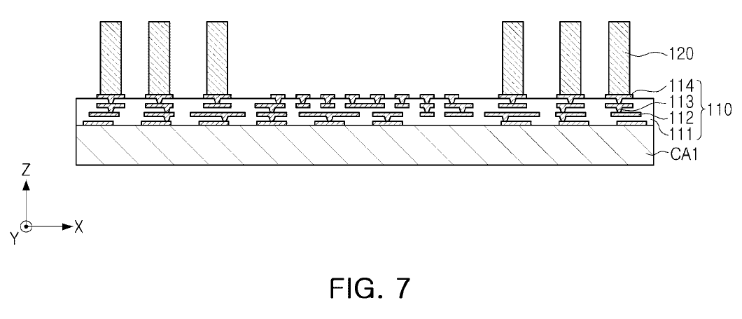

Referring to FIG. 7, conductive posts 120 may be formed on the lower redistribution structure 110.

The conductive posts 120 may be formed on the lower connection pads 114 by a plating process such as electrolytic plating or electroless plating. The conductive posts 120 may be formed by forming a photoresist pattern that exposes an area where the conductive posts 120 are to be formed, and forming a conductive material in the exposed area. In some implementations, the conductive posts 120 may include a metal such as copper (Cu), and a metal seed layer including titanium (Ti), copper (Cu), or the like may be formed on the lower surface thereof.

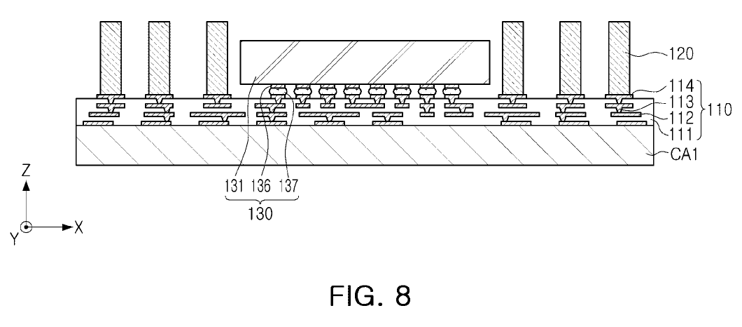

Referring to FIG. 8, the first semiconductor chip 130 may be bonded on the lower redistribution structure 110.

The first semiconductor chip 130 may include first connection bumps 136 and 137, and the first connection bumps 136 and 137 may be disposed on lower connection pads 114 and mounted in a flip-chip manner. The first semiconductor chip 130 may be connected to lower redistribution layers 112 through the first connection bumps 136 and 137.

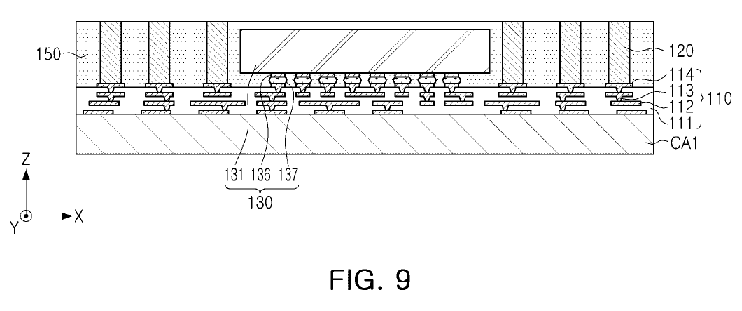

Referring to FIG. 9, an encapsulant 150 may be formed on the lower redistribution structure 110.

The encapsulant 150 may be formed to cover the conductive posts 120 and the first semiconductor chip 130 on the lower redistribution structure 110. In some implementations, the encapsulant 150 is formed to cover the conductive posts 120 and the upper surface of the first semiconductor chip 130, and then a planarization process may be performed on the encapsulant 150 and the conductive posts 120. The planarization process may include a grinding process, a Chemical Mechanical Polishing (CMP) process, or the like. The encapsulant 150 and the conductive posts 120 may be partially removed from the upper portion by the planarization process. The upper surfaces of the conductive posts 120 may be coplanar with the upper surface of the encapsulant 150 and may be exposed to the encapsulant 150. In some implementations, the upper surface of the first semiconductor chip 130 may be located at a lower level than the upper surface of the conductive posts 120, and the upper surface may be protected by the encapsulant 150.

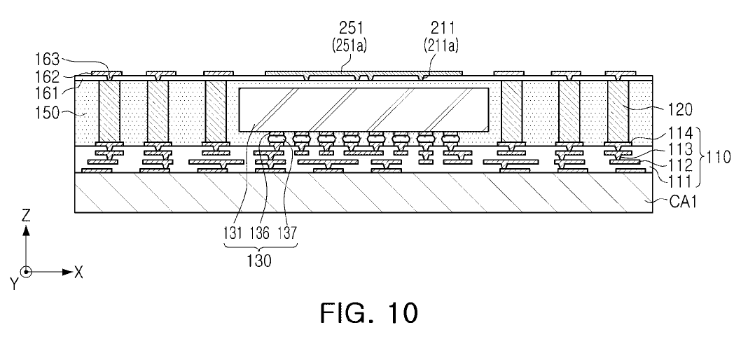

Referring to FIG. 10 together with FIG. 2A, the upper insulating layer 161, the upper redistribution layers 162, and a portion of the upper redistribution vias 163, and the first mesh pattern layer 251a and the lower heat dissipation vias 211a may be formed.

The upper insulating layer 161 may be formed by sequentially applying and curing a photosensitive material, for example, PID. The upper redistribution layers 162 and the upper redistribution vias 163, and the first mesh pattern layer 251a and the lower heat dissipation vias 211a may be formed by performing an exposure process and a development process to form a via hole penetrating the upper insulating layer 161, and patterning a metal material on the upper insulating layer 161 using a plating process. The first mesh pattern layer 251a may be formed to include first through-holes 251Ha.

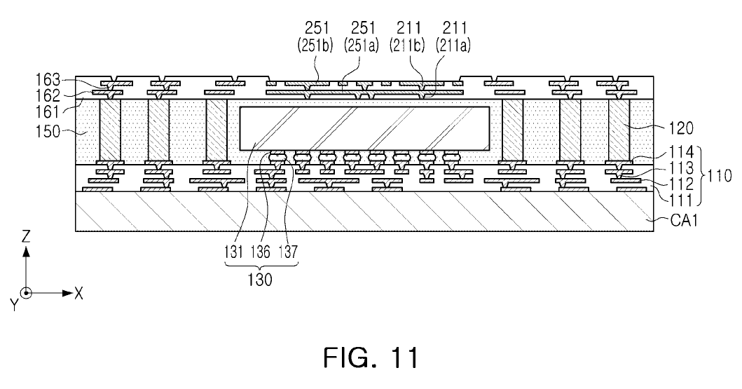

Referring to FIG. 11 together with FIGS. 2B and FIG. 3, a portion of the upper insulating layer 161, upper redistribution layers 162, and upper redistribution vias 163 may be further formed, and the second mesh pattern layer 251b and intermediate heat dissipation vias 211b may be formed.

The second mesh pattern layer 251b may be formed to include second through-holes 251Hb. As illustrated in FIG. 3, the second through-holes 251Hb may be formed to be misaligned relative to the first through-holes 251Ha along a plane perpendicular to a vertical direction. Since the second through-holes 251Hb are formed to be misaligned relative to the first through-holes 251Ha along a plane perpendicular to the vertical direction, the gas generated in the upper insulating layer 161 filling the first through-holes 251Ha may be smoothly discharged during the process. Accordingly, the process reliability may be improved while forming a plurality of mesh pattern layers 251 in the upper insulating layer 161. In some implementations, the gas generated in the upper insulating layer 161 may be generated from a solvent included in the PID. The intermediate heat dissipation vias 211b may be formed so as not to overlap with the first through-holes 251Ha and the second through-holes 251Hb in the vertical direction.

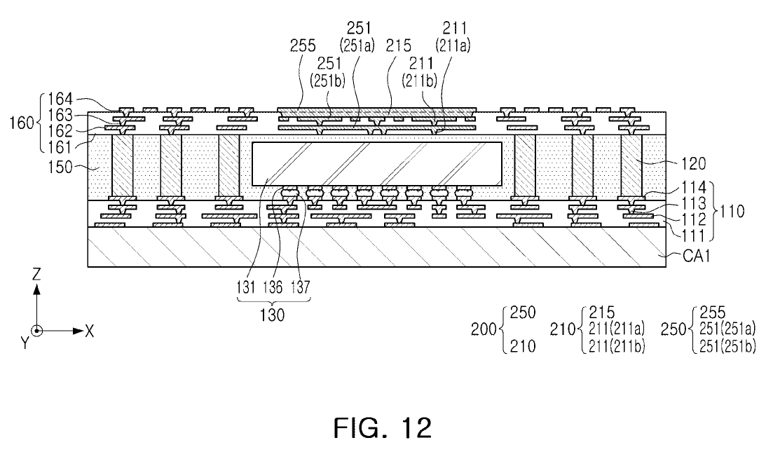

Referring to FIG. 12 together with FIGS. 2B and FIG. 2C, an upper insulating layer 161, upper redistribution vias 163, and upper connection pads 164 may be further formed to form an upper redistribution structure 160, and a plate layer 255 and an upper heat dissipation via 215 may be formed to form a heat dissipation structure 200.

The upper heat dissipation via 215 may be formed by forming a via hole penetrating the upper insulating layer 161 so that at least a portion of the upper surface of the second mesh pattern layer 251b and at least a portion of the second through-holes 251Hb are exposed, and then formed together with the plate layer 255 using a plating process. As illustrated in FIG. 2B and FIG. 2C, the upper surface 215_US of the upper heat dissipation via 215 may cover an area except for a portion of the edge of the lower surface of the plate layer 255, and the lower surface 215_LS of the upper heat dissipation via 215 may be formed to cover at least a portion of the second through-holes 215Hb and at least a portion of the upper surface of the second mesh pattern layer 251b. As in the process of FIGS. 10 - 12, the heat dissipation structure 200 may be formed together with the upper redistribution structure 160 without a separate additional process operation, so that the process operation may be simplified and the process cost may be reduced.

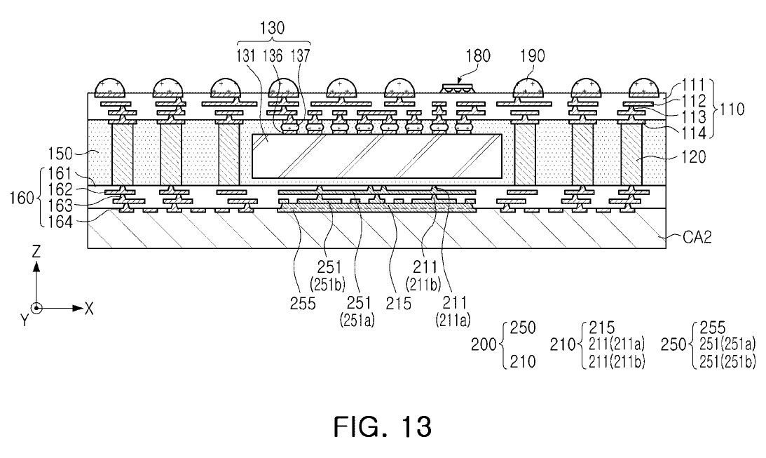

Referring to FIG. 13, the passive element 180 and external connection conductors 190 may be formed.

In some implementations, a second carrier CA2 is formed on the upper redistribution structure 160, and the package may be turned over to perform a subsequent process. The first carrier CA1 may be removed to expose an upper surface (based on FIG. 13) of the lower redistribution structure 110, and a surface of the lower redistribution layers 112 located at the uppermost side (based on FIG. 13) may be exposed. External connection conductors 190 may be formed on the exposed lower redistribution layers 112. A passive element 180 may be formed to be electrically connected to some of the lower redistribution layers 112. In some implementations, after forming the passive element 180 and the external connection conductors 190, a cutting operation of cutting the package into individual package units may be performed.

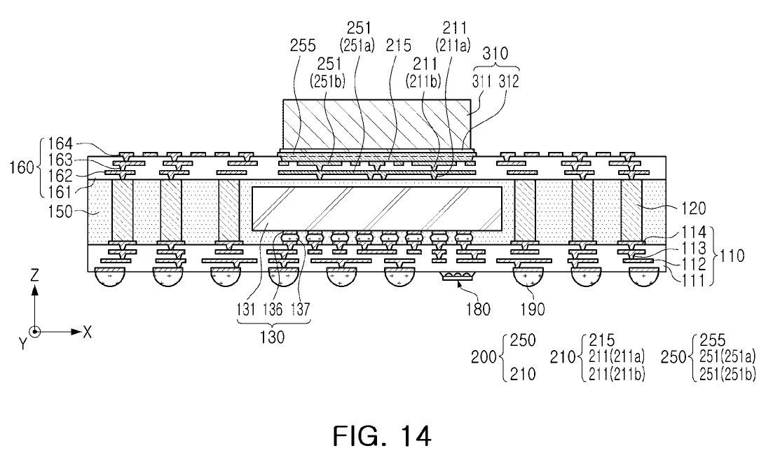

Referring to FIG. 14, a heat dissipation member 310 may be bonded on a heat dissipation structure 200.

In some implementations, the second carrier CA2 may be removed to expose the upper surface of the upper redistribution structure 160, and a subsequent process may be performed. The heat dissipation member 310 may be bonded on the upper surface of the plate layer 255 of the heat dissipation structure 200. The heat slug 311 of the heat dissipation member 310 may be bonded on the upper surface of the plate layer 255 by a thermal interface material layer 312.

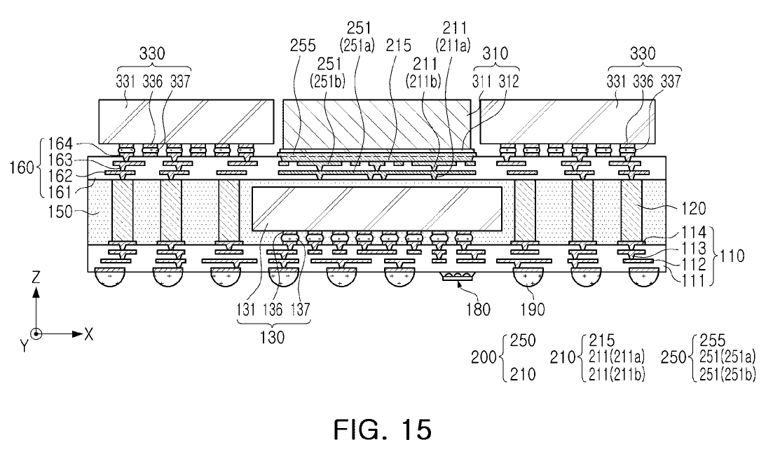

Referring to FIG. 15, second semiconductor chips 330 may be bonded on the upper redistribution structure 160.

In some implementations, the second semiconductor chips 330 may be symmetrically bonded to both sides of the heat dissipation member 310. In some implementations, the second semiconductor chips 330 may be bonded first and then the heat dissipation member 310 may be bonded. The second semiconductor chip 330 may include second connection bumps 336 and 337, and the second connection bumps 336 and 337 may be disposed on upper connection pads 164 and mounted in a flip-chip manner. The second semiconductor chip 330 may be connected to the upper redistribution layers 162 through the second connection bumps 336 and 337. Thereafter, referring to FIG. 1B together, an upper underfill 350 may be further formed to fill at least a portion of the space between the heat dissipation member 310 and the second semiconductor chips 330 on the upper redistribution structure 160, and the semiconductor package 10 of FIG. 1B may be manufactured.

As set forth above, in a structure including a heat dissipation member and a semiconductor chip disposed on an upper redistribution structure, the heat dissipation member and the semiconductor chip may be symmetrically disposed to improve the warpage phenomenon of the semiconductor package. The heat dissipation structure providing a thermal path below the heat dissipation member may include a heat dissipation layer having a mesh pattern, thereby improving heat dissipation characteristics. Accordingly, a semiconductor package with improved reliability and a method of manufacturing the same may be provided.

According to example implementations, a method of manufacturing a semiconductor package includes forming a lower redistribution structure including a lower insulating layer and lower redistribution layers within the lower insulating layer; forming conductive posts on the lower redistribution structure; bonding a first semiconductor chip on the lower redistribution structure; forming an encapsulant covering the semiconductor chip and the conductive posts, on the lower redistribution structure; forming an upper redistribution structure including an upper insulating layer and upper redistribution layers within the upper insulating layer, on the encapsulant, and a heat dissipation structure including a plurality of heat dissipation layers spaced apart from each other in a vertical direction; bonding a heat dissipation member connected to the heat dissipation structure, on the upper redistribution structure; and bonding second semiconductor chips electrically connected to the upper redistribution layers, on the upper redistribution structure. The plurality of heat dissipation layers of the heat dissipation structure include mesh pattern layers formed in the upper insulating layer and each including a plurality of through-holes, and a plate layer formed on the upper insulating layer.

In the method of manufacturing a semiconductor package, the mesh pattern layers of the heat dissipation structure may include a first mesh pattern layer including a plurality of first through-holes and a second mesh pattern layer including a plurality of second through-holes, and the plurality of second through-holes may be disposed to be misaligned relative to the plurality of first through-holes along a plane perpendicular to the vertical direction.

In the method of manufacturing a semiconductor package, the heat dissipation structure may further include a plurality of heat dissipation vias extending in the vertical direction within the upper insulating layer and connecting the first mesh pattern layer and the second mesh pattern layer, and the plurality of heat dissipation vias may be disposed to be misaligned relative to the plurality of first through-holes and the plurality of second through-holes along a plane perpendicular to the vertical direction.

In the method of manufacturing a semiconductor package, the second semiconductor chips may be disposed on both sides of the heat dissipation member, the heat dissipation structure may overlap the first semiconductor chip in the vertical direction, and at least some of the conductive posts may overlap the second semiconductor chips in the vertical direction.

In the method of manufacturing a semiconductor package, the mesh pattern layers of the heat dissipation structure may be formed by the same process as a process of the upper redistribution layers.

In the method of manufacturing a semiconductor package, the heat dissipation structure may include the same material as a material of the upper redistribution layers.

The method of manufacturing a semiconductor package may further include forming an upper underfill filling at least a portion of a space between the heat dissipation member and the second semiconductor chips.

In the method of manufacturing a semiconductor package, the heat dissipation member may include a thermal interface material layer on the plate layer and a heat slug on the thermal interface material layer.

In the method of manufacturing a semiconductor package, a planar area of the plate layer may be larger than a planar area of the heat slug, and the planar area of the plate layer may be larger than a planar area of each of the mesh pattern layers.

The method of manufacturing a semiconductor package may further include forming external connection conductors electrically connected to the lower redistribution layers, below the lower redistribution structure.

While this specification contains many specific implementation details, these should not be construed as limitations on the scope of any invention or on the scope of what may be claimed, but rather as descriptions of features that may be specific to particular implementations of particular inventions. Certain features that are described in this specification in the context of separate implementations can also be implemented in combination in a single implementation. Conversely, various features that are described in the context of a single implementation can also be implemented in multiple implementations separately or in any suitable subcombination. Moreover, although features may be described above as acting in certain combinations, one or more features from a combination can in some cases be excised from the combination, and the combination may be directed to a subcombination or variation of a subcombination.

While example implementations have been illustrated and described above, it will be apparent to those skilled in the art that modifications and variations could be made without departing from the scope of the present disclosure as defined by the claims below.

What is claimed is:

1. A semiconductor package comprising:
a lower insulating layer;
lower redistribution layers within the lower insulating layer;
a semiconductor chip on the lower insulating layer and electrically connected to the lower redistribution layers;
an encapsulant on the lower insulating layer and covering the semiconductor chip;
an upper insulating layer on the encapsulant;
upper redistribution layers within the upper insulating layer and electrically connected to the lower redistribution layers;
a heat dissipation member on the upper insulating layer; and
a heat dissipation structure below the heat dissipation member and including a plurality of heat dissipation layers spaced apart from each other in a vertical direction,
wherein the plurality of heat dissipation layers of the heat dissipation structure include
a first mesh pattern layer within the upper insulating layer and including a plurality of first through-holes;
a second mesh pattern layer at a higher level than the first mesh pattern layer within the upper insulating layer and including a plurality of second through-holes disposed misaligned relative to the plurality of first through-holes along a plane perpendicular to the vertical direction; and
a plate layer on the upper insulating layer and contacting the heat dissipation member.

2. The semiconductor package of claim 1, wherein at least some of the plurality of second through-holes overlap an area between the plurality of first through-holes along the plane perpendicular to in the vertical direction.

3. The semiconductor package of claim 1, wherein a number of the plurality of first through-holes included in the first mesh pattern layer is different from a number of the plurality of second through-holes included in the second mesh pattern layer.

4. The semiconductor package of claim 1, wherein the heat dissipation structure is spaced apart from the semiconductor chip.

5. The semiconductor package of claim 1, wherein the heat dissipation structure includes:
a plurality of intermediate heat dissipation vias connecting the first mesh pattern layer and the second mesh pattern layer within the upper insulating layer; and
an upper heat dissipation via connecting the second mesh pattern layer and the plate layer within the upper insulating layer,
wherein the plurality of intermediate heat dissipation vias are misaligned relative to the plurality of first through-holes and the plurality of second through-holes along the plane perpendicular to the vertical direction, and
the upper heat dissipation via overlaps at least some of the plurality of second through-holes in the vertical direction.

6. The semiconductor package of claim 1, wherein the heat dissipation structure includes:
a plurality of intermediate heat dissipation vias connecting the first mesh pattern layer and the second mesh pattern layer within the upper insulating layer; and
a plurality of upper heat dissipation vias connecting the second mesh pattern layer and the plate layer within the upper insulating layer,
wherein the plurality of intermediate heat dissipation vias are misaligned relative to the plurality of first through-holes and the plurality of second through-holes along the plane perpendicular to the vertical direction, and
the plurality of upper heat dissipation vias are misaligned relative to the plurality of second through-holes along the plane perpendicular to the vertical direction.

7. The semiconductor package of claim 1, wherein the heat dissipation structure is electrically isolated from the upper redistribution layers and the semiconductor chip.

8. The semiconductor package of claim 1, wherein the heat dissipation structure includes the same material as the upper redistribution layers.

9. The semiconductor package of claim 1, wherein the heat dissipation structure includes lower heat dissipation vias extending in the vertical direction below the first mesh pattern layer and contacting the encapsulant.

10. The semiconductor package of claim 9, wherein the lower heat dissipation vias are spaced apart from the semiconductor chip.

11. The semiconductor package of claim 1, wherein the heat dissipation member includes:
a thermal interface material layer on an upper surface of the plate layer of the heat dissipation structure; and
a heat slug on the thermal interface material layer.

12. The semiconductor package of claim 1, wherein the upper redistribution layers include:
first upper redistribution layers positioned at the same level as the first mesh pattern layer; and
second upper redistribution layers positioned at the same level as the second mesh pattern layer.

13. The semiconductor package of claim 1, comprising an upper underfill surrounding a portion of the heat dissipation member on the upper insulating layer.

14. A semiconductor package comprising:
a lower redistribution structure including a lower insulating layer and lower redistribution layers within the lower insulating layer;
a first semiconductor chip on the lower redistribution structure and electrically connected to the lower redistribution layers;
an encapsulant on the lower redistribution structure and covering the first semiconductor chip;
an upper redistribution structure on the encapsulant and including an upper insulating layer and upper redistribution layers within the upper insulating layer;
conductive posts extending in a vertical direction within the encapsulant and electrically connecting the lower redistribution layers and the upper redistribution layers;
a heat dissipation member on the upper redistribution structure;
second semiconductor chips on at least both sides of the heat dissipation member, wherein the second semiconductor chips are on the upper redistribution structure and electrically connected to the upper redistribution layers; and
a heat dissipation structure below the heat dissipation member, wherein the heat dissipation structure includes a plurality of heat dissipation layers spaced apart from each other in a vertical direction and a plurality of heat dissipation vias connecting the plurality of heat dissipation layers,
wherein an uppermost heat dissipation layer among the plurality of heat dissipation layers is on the upper insulating layer and contacts the heat dissipation member,
remaining heat dissipation layers among the plurality of heat dissipation layers are within the upper insulating layer, and
each remaining heat dissipation layer among the plurality of heat dissipation layers includes a plurality of through-holes.

15. The semiconductor package of claim 14, wherein in the vertical direction,
the heat dissipation member overlaps the first semiconductor chip, and
at least some of the conductive posts overlap the second semiconductor chips.

16. The semiconductor package of claim 14, wherein the first semiconductor chip includes a logic chip, and
each second semiconductor chip includes a memory chip.

17. The semiconductor package of claim 14, comprising an upper underfill filling at least a portion of a space between the heat dissipation member and the second semiconductor chips on the upper redistribution structure.

18. A semiconductor package comprising:
a lower redistribution structure including a lower insulating layer and lower redistribution layers within the lower insulating layer;
a semiconductor chip on the lower redistribution structure and electrically connected to the lower redistribution layers;
an encapsulant on the lower redistribution structure and covering the semiconductor chip;
an upper redistribution structure on the encapsulant and including an upper insulating layer and upper redistribution layers within the upper insulating layer;
a heat dissipation member on the upper redistribution structure and including a thermal interface material layer and a heat slug on the thermal interface material layer; and
a heat dissipation structure below the heat dissipation member and including a plurality of heat dissipation layers spaced apart from each other in a vertical direction,
wherein the plurality of heat dissipation layers include internal heat dissipation layers within the upper insulating layer and an upper heat dissipation layer on the upper insulating layer, and
a planar area of the upper heat dissipation layer is larger than a planar area of each internal heat dissipation layer.

19. The semiconductor package of claim 18, wherein each internal heat dissipation layer includes a plurality of through-holes.

20. The semiconductor package of claim 18, wherein a planar area of the upper heat dissipation layer is larger than a planar area of each thermal interface material layer and a planar area of the heat slug.
